(19) United States
(12) Patent Application Publication
(10) Pub. No.: US 2023/0178369 A1
(43) Pub. Date: Jun. 8, 2023

(54) METHOD OF GROWING SEMICONDUCTOR NANOWIRES USING A CATALYST ALLOY

(71) Applicant: ALIGNEDBIO AB, Lund (SE)

(72) Inventors: Magnus Tarlé BORGSTRÖM, Lund (SE); Patrick FLATT, Lund (SE); Lukas HRACHOWINA, Lund (SE)

(21) Appl. No.: 17/998,451

(22) PCT Filed: May 18, 2021
(86) PCT No.: PCT/IB2021/000387

§ 371 Date: Nov. 10, 2022

Related U.S. Application Data
(60) Provisional application No. 63/026,869, filed on May 19, 2020.

(51) Int. Cl. H01L 21/02

(52) U.S. Cl. CPC H01L 21/02603; H01L 21/02392; H01L 21/02543; H01L 21/0262

(57) ABSTRACT

A method of growing nanowires includes forming catalyst particles including a gold-indium alloy on portions of a semiconductor substrate that are exposed by openings of a template layer disposed on the substrate, and growing the nanowires including a compound semiconductor material, such as AlP, GaP, etc., under the catalyst particles. The substrate may be reused after removing the nanowires from the substrate.

### RELATED APPLICATION

This application claims the benefit of priority to U.S. Provisional Application No. 63/026,869, filed May 19, 2020, the entire contents of which are incorporated herein by reference.

### FIELD

The present invention is directed to a method of growing semiconductor nanowires in general, and to growing semiconductor nanowires through a mask using a catalyst alloy in particular.

### BACKGROUND

An article by R. Jam, et. al., “Embedded sacrificial AlAs segments in GaAs nanowires for substrate reuse” in Nanotechnology 31 (2020) 204002 describes growing GaAs nanowires on a GaAs substrate through openings in a silicon nitride (SiN) mask. As shown in FIG. 1A, a tri-layer mask (e.g., silicon nitride, lift-off resist (LOR) and polymer resist (TU7)) is patterned by nanoimprint lithography. A gold catalyst particle (Au seed) is deposited in the openings in the mask as shown in FIG. 1B. The Au seed is used as a catalyst to grow a GaAs nanowire with an AlAs base via seeded vapor-liquid-sold (VLS) growth, as shown in FIG. 1C. However, the method in the Jam et. al. article requires the formation of a GaAs stub on the GaAs substrate in the openings in the mask before an AlAs nanowire stub can be grown on the GaAs stub. A GaAs nanowire (NW) is then grown on the AlAs stub. The GaAs NWs are then embedded in a polymer matrix and mechanically removed from the substrate, as shown in FIG. 1D. The AlAs stubs are selectively removed from the mask openings by selective etching, leaving the GaAs stubs in the mask openings, as shown in FIG. 1E. The substrate with the mask is then reused, and the Au seed is again deposited in the openings in the mask using selective area (SA) electrodeposition, as shown in FIG. 1F. The GaAs stubs, AlAs nanowire stubs and the GaAs nanowires are again grown in a second growth cycle.

Since the GaAs stubs have the same composition as the GaAs substrate, they cannot be easily removed by selective etching and occupy the lower parts of the openings. In addition, SiN mask delamination from the GaAs surface may also occur at growth temperatures. These GaAs stubs limit the number of times the GaAs substrate may be reused because they eventually fill the entire height of the openings in the mask, making SA electrodeposition impossible. Furthermore, if the gold catalyst particles are formed by electroplating, then gold may plate the sidewalls of such GaAs stubs and even underplate the SiN mask, which negatively impacts nanowire growth. In addition, it may be difficult to remove the GaAs stubs by etching, since the substrate may be affected by the etchant. Etching may also result in unwanted surface roughness, under etching, and under plating of the SiN mask.

### SUMMARY

Various embodiments provide a method of growing nanowires, comprising forming catalyst particles including a gold-indium alloy on portions of a semiconductor substrate that are exposed by openings of a template layer disposed on the substrate, and growing the nanowires including a compound semiconductor material under the catalyst particles.

Various embodiments provide a method of growing nanowires (NWs), comprising depositing gold particles on portions of a gallium phosphide (GaP) substrate, performing an indium flush to alloy the gold particles with indium to form gold-indium alloy catalyst particles, growing aluminum phosphide (AlP) nanowire stubs between the substrate and the catalyst particles, and growing GaP NWs between the AlP nanowire stubs and the catalyst particles.

### BRIEF DESCRIPTION OF THE DRAWINGS

FIGS. 1A-1F illustrate schematic side cross sectional views which show the steps in a related art NW growth process.

FIGS. 2A-2F are schematic side cross sectional views illustrating the steps in a method of forming a seed layer including catalyst particles (i.e., seed particles) in openings of a template, according to various embodiments.

FIGS. 3A-3E are schematic side cross sectional views illustrating a method of NW growth and substrate reuse, according to various embodiments.

FIGS. 4A-4D, 5A-5D, 6A, 6B, 7A, 7B, 8A and 8B are micrographs which show NWs formed according to examples of the present disclosure.

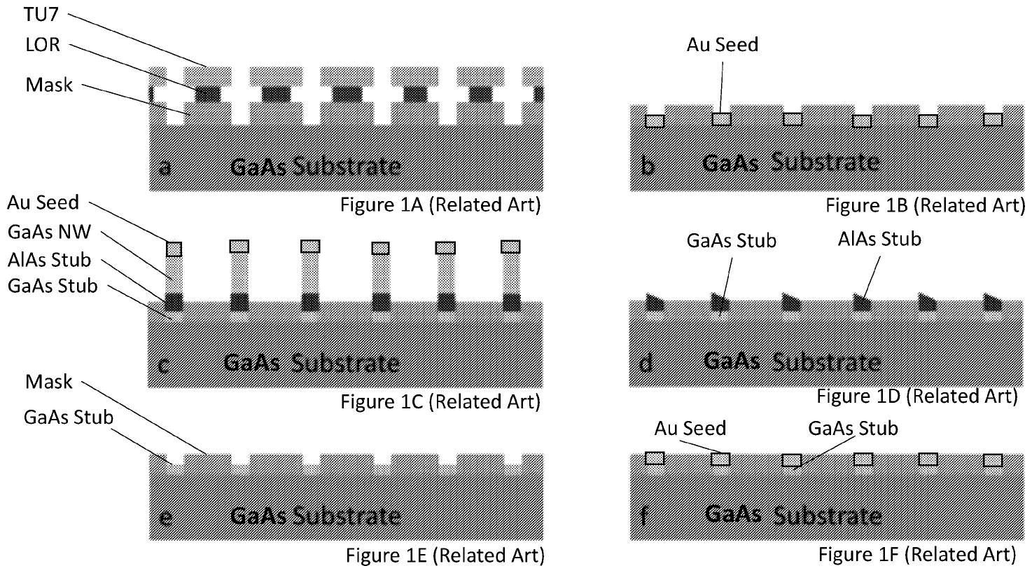

### DETAILED DESCRIPTION

The present inventors are unaware of previous reports of growth of AlP nanowires or nanowire portions directly on GaP substrates. The present inventors determined that AlP nanowires (or stub portions thereof) can be grown on a GaP substrate if the gold catalyst (i.e., seed) particle is alloyed with indium. However, no AlP nanowire growth on a GaP was observed without alloying indium with the gold catalyst particle.

In one embodiment, an indium flush is performed after gold catalyst particle deposition but before the AlP nanowire stub growth to alloy the gold catalyst particle with the indium before AlP nanowire stub growth. However, other alloying methods may be used, such as by pre-alloying gold with indium before depositing the gold-indium alloy catalyst particles from an Au—In alloy source on the GaP substrate, or simultaneously depositing gold and indium from gold and indium sources (e.g., by masked evaporation and lift off) to form the gold-indium alloy catalyst particles, or by using residual indium in the reaction chamber (e.g., by using an InP coated liner in the reaction chamber during AlP nanowire growth, where the liner is believed to act as a source of indium to form the Au—In alloy).

Compared with the method described in the article by Jam et al., the embodiment process is simpler and allows the reutilization of the GaP wafer several times. The process described in the article requires the growth of a small portion of GaAs under the Au particle every time an AlAs/GaAs NW is grown. In the embodiment process, this step is not needed (e.g., GaP NW stub does not have to be grown on the GaP substrate before growing the AlP stub/segment). By using the In flush or another Au—In alloying process, the GaP stub growth step may be omitted while still growing the AlP/GaP axial heterojunction NW. This facilitates the cleaning of the openings of the growth template (e.g. silicon nitride or another dielectric mask) and the initiation of a new NW growth process.

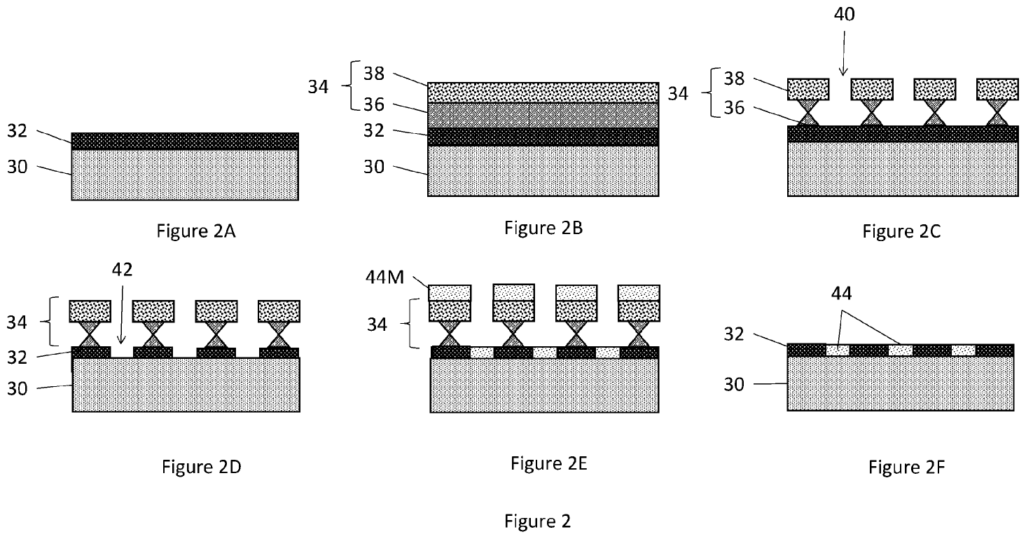

FIGS. 2A-2F are cross-sectional views showing the steps in a method forming seed or catalyst particle layer, according to various embodiments of the present disclosure. Referring to FIG. 2A, a template layer 32 may be deposited on a semiconductor substrate 30. The semiconductor substrate 30 may be formed of a semiconductor material, such as a GaP. However, other semiconductor materials, such as other III-V semiconductor materials, may also be used. The template layer 32 may be formed by depositing of a template material using any suitable deposition process. Herein, “suitable deposition processes” may include a chemical vapor deposition (CVD) process (including a high density plasma CVD (HDPCVD) process, a metalorganic CVD (MOCVD) process, a plasma enhanced CVD (PECVD) process, etc.), a physical vapor deposition (PVD) process (e.g., a sputtering process, etc.), an atomic layer deposition (ALD) process, laser ablation, or the like. Suitable template materials may include silicon nitride (SiN), silicon oxide, silicon oxynitride, or the like.

Referring to FIG. 2B, a mask 34 may be deposited on the template layer 32. In particular, the mask 34 may be formed by depositing a base layer 36 on the template layer 32, and by depositing a resist layer 38 on the base layer 36. The base layer 36 may be, for example, a bottom antireflective coating (BARC) or a lift-off resist (LOR). In some embodiments, the base layer 36 may be a polymethylglutarimide (PMGI) resist, such as PMGI SF3S polymer (MicroChem Corp, USA). The resist layer may be, for example, a nanoimprint resist (e.g., TU-7 resist) or a deep ultraviolet (UV) resist (e.g., PAR1085S90 (Sumitomo, Japan)).

Referring to FIG. 2C, the mask 34 may be patterned to form openings 40 that expose the template layer 32. For example, the mask 34 may be exposed by nanoimprint lithography, when the mask 34 includes a nanoimprint resist 38 and a LOR base layer 36, or by deep UV photolithography, when the mask 34 includes a deep UV resist 38 and a BARC base layer 36. After exposure, the mask 34 may be developed to form the openings 40 that expose the template layer 32. The openings 40 may be circular or polygonal (e.g., hexagonal) and have a width of from 75 to 200 nm, such as from 90 to 140 nm, from 100 to 130 nm, or from 110 to 120 nm.

Referring to FIG. 2D, an etching process, such as a dry etching process or a wet etching process, may be performed to form openings 42 in the template layer 32. The openings 42 may expose portions of the semiconductor substrate 30. The openings 42 may have the same width/dimensions as the openings 40.

Referring to FIG. 2E, a metal layer 44M, such as gold, a gold-indium alloy, or the like, may be deposited on the mask and in the openings 42. The metal layer 44M may be deposited using any suitable deposition process, such as physical vapor deposition or electrodeposition, for example.

Referring to FIG. 2F, the mask 34 may be removed by stripping or ashing, for example, such that metal particles 44 may remain on the substrate 30 in the openings 42 of the template layer 32. In other words, the portions of the metal layer 44M located on the mask are removed by a lift-off process.

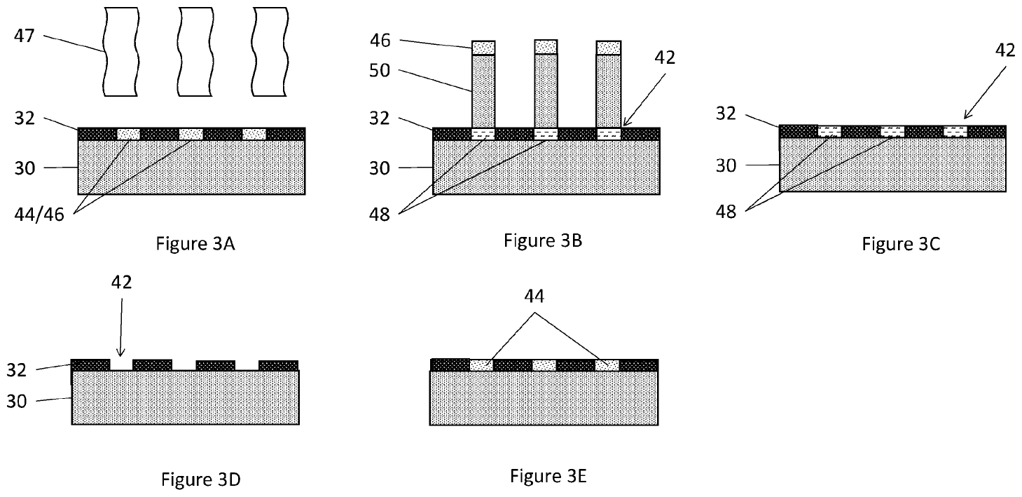

FIGS. 3A-3E show the steps of a method of growing NWs on a substrate 30 including metal particles 44, as shown in FIG. 2F. Specific details of these steps are described in more detail in the Examples below.

Referring to FIG. 3A, the substrate 30 may be disposed in a reaction chamber. If the metal particles 44 are formed of pure gold, then an indium flush may be conducted to alloy the gold with indium, such that the metal particles 44 are converted into catalyst particles 46 that comprise a gold-indium alloy catalyst. In some embodiments, the catalyst particles 46 may include gold, indium, aluminum, gallium, and a relatively small amount of phosphorous. The indium flush may be performed by flowing an indium containing vapor 47, such as trimethylindium (TMIn) or another indium containing metal organic vapor into the reaction chamber containing the substrate with the gold particles 44. In one embodiment, a phosphine gas is also flown into the reaction chamber at the same time as TMIn. However, the reaction chamber temperature is maintained below the phosphine pyrolysis/decomposition temperature and above the indium containing vapor (e.g., TMIn) pyrolysis/decomposition temperature to avoid forming indium phosphide nanowire portions under the catalyst particles 46. The temperature may be between 260° C. and 400° C., such as from 325° C. to 375° C., from 340° C. to 360° C., or about 350° C. The indium flush may continue for 10 to 360 seconds, such as 15 to 120 seconds, depending on the substrate size and/or amount of gold present on the substrate. The TMIn flow is then terminated.

Referring to FIG. 3B, nanowires 50 may be grown on the substrate 30, using the catalyst particles 46 as a growth catalyst. In particular, aluminum phosphide (AlP) nanowire stubs 48 may be grown in the openings 42, under the catalyst particles 46. The nanowire stubs 48 may be shorter or longer than the height of the openings 42. The specific AlP nanowire growth parameters are described below. For example, the substrate 30 may be annealed first at an elevated temperature, such as a temperature ranging from 600° C. to 700° C., from 625° C. to 675° C., or about 650° C., for a time period ranging from about 5 minutes to about 20 minutes, such as about 10 minutes, followed by lowering the reaction chamber temperature to the desired AlP deposition temperature ranging from 410° C. to 520° C., such as from 415° C. to 505° C., or from 440° C. to 480° C., and flowing phosphine and an aluminum-containing vapor, such as trimethyl aluminum (TMAl) into the reaction chamber to deposit AlP nanowire stubs.

Then, GaP nanowires 50 (e.g., GaP NW segments) are grown on the AlP nanowire stubs 48. The GaP nanowires 50 may be grown by changing the aluminum-containing vapor to a gallium-containing vapor, such as trimethyl gallium (TMGa). In particular, the flow of the aluminum-containing vapor may be stopped without stopping the phosphine flow, a flow of acid may be provided for a period of time, and then the gallium-containing vapor flow may be started. In particular, an acid (e.g., HCl or HBr) may be provided during a transition period of at least 10 seconds, such as from 10 seconds to about 60 seconds, or from 15 seconds to 30 seconds, before the flow of the aluminum-containing vapor is stopped and before the gallium-containing vapor flow is started.

Referring to FIG. 3C, the nanowires 50 may be removed from the substrate 30 using any suitable method. For example, the nanowires 50 may be removed using sonication. Alternatively, the nanowires 50 may be incorporated into a polymer matrix (e.g., a polydimethylsiloxane (PDMS) matrix) and then mechanically removed from the substrate 30.

Referring to FIG. 3D, the AlP stubs 48 are removed from the openings 42 in the template layer 32 by selective etching. Any suitable etching solution, such as an aqueous HCl solution, may be used which etches AlP selective to the GaP material of the substrate 30 and to the template material (e.g., SiN). Specific etching methods are described below. The etching exposes the GaP substrate 30 in the openings 42.

Referring to FIG. 3E, the substrate 30 may be reused to grow additional AlP/GaP nanowires. In particular, gold catalyst particles 44 may be deposited in the openings in the mask using electrodeposition, for example. Then, steps of FIGS. 3A-3E may be repeated to form additional nanowires. The process may be repeated two or more times, such as three to ten times, or five to ten times, while reusing the same substrate 30 and template 32.

Referring to FIGS. 3A to 3E, a method according to one embodiment includes the following steps. The substrate 30 containing the gold particles 44 is provided with a moderate amount of indium at relatively low temperature (e.g., 350° C.) to form the Au—In alloy catalyst particles 46. These Au—In catalyst particles are heated to a relatively high temperature (e.g., 650° C.) and annealed under phosphine flow for several minutes. After annealing, the substrate is cooled down to an intermediate growth temperature (e.g., 440° C.), where the growth of AlP is initiated. Shortly before the material transition from AlP to GaP, the acid (e.g., HCl) is introduced to facilitate the transition and the GaP nanowire growth. During the transition, AlP growth is replaced with GaP growth. The first section of the GaP section 50 is grown with a linearly increasing amount of Group-III, and the remainder of the nanowire 50 is grown with the highest Group-III content. Thus, the step of growing the GaP NWs 50 comprises initially growing the GaP NWs 50 with a linearly increasing amount of gallium from a first amount to a higher second amount, followed by growing the GaP NWs 50 with the second amount of gallium for a predetermined time, preferably until completion of the growth of the GaP NWs 50.

### Examples

The following exemplary embodiments describe wafer processing, the optimization of NW growth, etch characterization of GaP and AlP, as well as the substrate reuse experiments.

Wafer processing describes the steps taken to prepare the wafers into the substrates later used for the NW growth. NW growth optimization describes NW growth recipes. Etch characterization described methods used for etching of AlP and GaP. Lastly, the substrate reuse experiments are discussed.

### Substrates

The wafers used during the entirety of the project were three S-doped (111)B GaP wafers, 2 inch (50.8 mm) with a thickness of 300 μm. The wafers were in different conditions when they were received. For convenience, they will be called wafer 1, 2 and 3 respectively.

### Wafer 1

Wafer 1 was still sealed from the manufacturer, thereby being in the best condition possible. This wafer was used for the substrate reuse experiments enabled by a sacrificial layer of AlP.

### Wafer 2

Wafer 2 was exposed to a non-clean room environment before processing. It therefore had to be cleaned before processing could begin. After cleaning it should again be in a very good condition. It is used for the optimization of the NW growth, described below.

### Wafer 3

GaP stubs were present on the surface of Wafer 3 from a previous GaP NW growth. Wafer 3 was used to investigate whether it is possible to perform epitaxial growth of GaP NWs on this substrate after surface planarization by chemical etching.

Si wafers were used during processing as dummy wafers to test processing steps before using the more expensive GaP substrates.

### Pre-Processing

Wafer 1 was ready for processing. Wafer 2 and 3 however had to be prepared with some pre-processing before the real processing could be started.

The wafer that was exposed to a non-clean room environment, Wafer 2, was cleaned with acetone and isopropanol, to assure that no contaminants were on the substrate surface that could impact processing.

Efforts were made to reuse Wafer 3, on which GaP NWs had previously been grown. The NWs had already been removed by sonication, leaving stubs on the surface that were at least partially removed by chemical etching. Diluted aqua regia, H₂O:HCl:HNO₃, was mixed at a ratio of 3:3:2 and used as the etching solution. Wafer 3 was etched twice for 5 minutes at 23° C. Finally Wafer 3 was etched for another 2 minutes at 45° C. After every etch cycle the wafer surface was visually inspected in SEM. The wafer surface was desired to be as flat as possible, without significant removal of bulk material.

### Wafer Processing

Wafer processing includes all the steps that were taken to convert the bare wafers into the substrates used for the experiments. The processing steps are schematically illustrated in FIGS. 2A-2F.

The first processing step was to deposit the SiN mask on the wafers. Thereafter the nitride mask was patterned using displacement Talbot lithography and reactive ion etching (RIE). Lastly the gold seed particles used for NW growth were defined using evaporation and lift-off.

The structure of the processing was the same for all three wafers, with only minor differences as described below.

### Mask Deposition

The first process step was to deposit a 75 nm thick SiN mask. The SiN mask was deposited using a Micro Systems 200 ICP PE-CVD system. The CVD reactor was first loaded with a Si dummy wafer to ensure that all parameters were set correctly and to get an estimate of the deposition rate. After deposition on the dummy wafer, the thickness of the SiN layer was measured using ellipsometry and the deposition rate was calculated. Here, no changes were needed and the same process was repeated on the GaP wafer. The resulting thickness of the SiN layer on these wafers was also determined by ellipsometry since it is important for further processing steps. After this step the wafers were in the same state as shown in FIG. 2A.

### Lithography

The first step to transfer the nanopattern into the SiN mask is the lithography. Here displacement Talbot lithography, DTL, was used with a Phalber 100 DUV system, capable of sub-100 nm resolution. Before exposure in the Talbot system the wafers were coated with two layers of developable resists. First a layer of a bottom anti-reflection coating, SF 3S, and then a layer of deep-UV resist, PAR1085S90. After applying the double-layer of resists, the wafer was exposed by DTL. To find an appropriate dose, two different exposure doses were tested on Wafer 2. Half of the wafer was exposed with a dose of 3.0 mJ/cm² and the other half with 3.5 mJ/cm². The other two wafers, Wafer 1 and 3, were exposed with a dose of 3.25 mJ/cm². After exposure by DTL the resists were developed in developer MF24A. After the developing, the wafers were as in FIG. 2C.

### Pattern Transfer

After the Talbot lithography, the nanopattern was in the resist, but not in the SiN mask yet. RIE was used to transfer the pattern into the SiN mask. The RIE was carried out in a Sirus T2 Plus table-top RIE system. The etch that was performed does not etch the resists used, and is, as described earlier, an anisotropic etching technique. Hence only the SiN exposed below the openings in the resist was etched.

The etch rate of the tool was drifting, hence a Si dummy wafer, prepared in the same way as all the wafers, was used to experimentally determine the etch rate. The thickness of the SiN on the dummy wafer was measured with ellipsometry before and after etching, giving an etch rate of 0.322 nm/s. For the GaP Wafers 1, 2 and 3, the time of the etch program was set to 233 seconds, therefore etching 75 nm, which corresponded to the thickness of the deposited SiN mask on the GaP wafers. Etching this exact amount enabled to etch all of the SiN without affecting the substrate. After the RIE the wafer was dipped in a diluted HF solution, HF:H₂O at a ratio of 1:100, to remove any residues of SiN in the holes of the SiN mask.

After the above process step, the SiN mask was patterned the same way as the resist was patterned by the DTL, so the pattern had been transferred into the SiN mask as shown in FIG. 2D.

### Seed Particle Deposition

After the previous processing step, the patterning of the SiN mask by RIE, the gold seed (i.e., catalyst) particles were defined on the wafers by using evaporation followed by a lift-off procedure. Smaller substrate pieces were later used to optimize the electroplating process. For evaporation, a Temescal E-Beam evaporator, was set to deposit 65 nm of 24K gold, 99.95% purity. Depositing this amount leaves approximately 10 nm room in the holes of the SiN mask to facilitate lift-off and growth. The same deposition was done on all three wafers.

Evaporation covered the entire surface of the wafers in gold, as shown in FIG. 2E. To remove the excessive gold, which is on top of the resist, a lift-off procedure was performed using remover 1165. After lift-off there should only be gold inside the holes of the SiN mask, giving nicely defined seed particles for the NW growth that followed next. The wafers were cleaned with ozone before growth, in order to remove any organic residues on the wafer. A schematic of the substrate after finished processing is shown of FIG. 2F.

### Wafer Dicing

After the seed particle definition the wafers were divided into smaller substrates to suit different experiments. Wafer 1, which was used for the reuse experiments, was diced in 1×1 cm² pieces with a Disco DAD 3320 dicer. This was done so that the samples would fit the holder for electroplating and also yield more material for use. Wafer 2, which was used for the growth optimization, was broken into small pieces with a diamond tip pen. This was done to be able to carry out many growth experiments on the limited substrate area, minimizing costs. Wafer 3, which was planarized by chemical etching, was also divided with a diamond tip pen, but into larger pieces.

After processing of the wafers were finished, NW growth was initiated. First, recipes for the growth were designed and tested. Substrates of Wafer 2 were used to find the right growth conditions that later would be used for the experiments on Wafers 1 and 3. We started with optimization of the GaP growth, then the AlP growth and lastly the growth of axial AlP/GaP NWs.

### Etch and Cover Run

Before any NW growth could be done, the reactor was prepared. Before every experiment session, a fresh liner was placed in the reactor and an InP or GaP etch and cover run was performed. This step, which is similar to a growth recipe, is used to set equal conditions for the thereafter following growth-experiments. The reason an etch and cover run was used, was to increase the reproducibility of the experiments while being more time efficient than using a freshly cleaned liner for every experiment.

### Growth Recipes

Growth recipes define the conditions that the samples are exposed to while being in the reactor; before, during and after growth. To grow NWs, the growth recipes needed to be optimized. For GaP this meant to test known recipes and adjust them to the specific MOVPE reactor used, an Aixtron 200/4. For the AlP and AlP/GaP growth completely new recipes were designed from the ground up. The recipes were optimized by making changes to the growth conditions, maximizing the ratio of straight growing wires and kinked wires, which may be referred to herein as yield.

The growth recipes used were structured as in the list below.

1. InP covered reaction chamber (i.e., InP covered liner in the chamber)
(a) High Temperature Annealing
(b) Growth

2. GaP covered reaction chamber (i.e., GaP covered liner in the chamber)
(a) Indium Flush
(b) High Temperature Annealing
(c) Growth

### Growth Characterization

The NW growth was investigated in-situ with the use of a custom built LayTec-Spectrum. After growth, the NWs were thoroughly investigated in either a SEM-LEO 1560 Thermal Field Emission SEM or a Hitachi SU8010 Cold Field Emission SEM, depending on availability of the tools. LayTec was used to control NW length on the substrates while the SEM images were analyzed, using the software ImageJ, to determine the exact NW length and diameter as well as quantifying the yield of the growth.

### GaP Etch

Prior to the surface planarization of Wafer 3 by chemical etching, etching characteristics of GaP NWs were investigated to find the etching conditions that Wafer 3 would be exposed to.

The GaP NWs that were etched were previously grown from substrates of Wafer 2. The etching was done at different temperatures and durations, using diluted aqua regia, H₂O:HCl:HNO₃ at a ratio of 3:3:2. To characterize the etch rate of GaP NWs, different etch durations and temperatures were investigated.

The etching was characterized using small substrate pieces from the wafer used for growth optimization. GaP NWs were then grown on these substrates. It should be noted that these samples had a SiN mask, covering the GaP surface of the substrate, however Wafer 3 that would be etched did not. Therefore no etch characterization of the surface could be done on these substrates prior to etching Wafer 3.

### AlP Etch

The etching experiments were carried out on samples having only AlP NWs, and no GaP segments. This was done to more easily be able to characterize the etching characteristics of the AlP. The etching solutions tested were DI-water, diluted HCl mixtures and a diluted piranha etch. Different solutions were tested to find the etching solution that later was used for the regrowth experiments. The purpose of the etching in the regrowth perspective is in changing the substrate to remove the remaining AlP stubs after NW harvesting/removal. This results in a clean and exposed substrate surface in the openings of the growth mask, allowing for redeposition of the Au seed particles.

### Substrate Reuse

To test the potential of regrowth, axial AlP/GaP NWs were grown on the previously prepared 1×1 cm² substrates from Wafer 1. The GaP segments of the NWs (e.g., GaP nanowires) were harvested by sonication. AlP residues were then removed by etching the samples in HCl:H₂O at a ratio of 1:1. After etching, the substrates should again be in the state as in FIG. 3D

To redefine the gold seed particles on the pieces from Wafer 1, electroplating was used, where the insulating SiN mask acts as a template, allowing for selective area electrodeposition. The set-up for the electroplating was based on a system from Yamamoto-MS. The electroplating was performed as disclosed below.

After electroplating the Au seed particles had been redefined and the substrates were ready for regrowth. However before the substrates were moved to the reactor for regrowth, any organic residues that might had been deposited from the electrolyte solution had to be removed. This was done by an ozone cleaning process.

After ozone cleaning of the pieces from Wafer 1 were moved to the MOVPE reactor where they were exposed to the same growth recipe as before. Two cycles of regrowth and removal, as described above, were carried out, meaning NWs had been grown and removed from the same substrates three times.

### Substrate Cleaning

The cleaning procedure for Wafer 2 was to place the wafer into a beaker filled with acetone, which was placed in an ultrasonic bath for 10 minutes. Wafer 2 was then transferred to a beaker with isopropanol, which also was placed in an ultrasonic bath for 10 minutes. Wafer 2 was then removed from the isopropanol and blow dried with a nitrogen gun. The cleaned wafer was thereafter placed in the sample box and ready for processing.

### GaP Wafer Etch

The etchant investigated for the GaP etch was aqua regia. Since the interest here lies in etching on the nanoscale, and it not being desired to etch bulk, a diluted solution was used. A mixture of H₂O:HCl:HNO₃ at a 3:3:2 volume ratio, was prepared. After mixing the mixture was left to rest for 15 minutes. For the etching at room temperature, 23° C., Wafer 2 was submerged in 100 ml of the etching solution. During etching the solution was slightly stirred. After 5 minutes the wafer was transferred to a large beaker with DI water which then was placed under flowing DI-water so that the beaker was overflowing. After SEM inspection the wafer was etched again in the same way. Lastly, after another visual inspection in SEM, Wafer 2 was etched at 45° C. for 2 minutes. This was done by heating the etching solution on a hotplate.

### Mask Deposition

The temperature of the reaction chamber of the PECVD system was set to 250° C., which resulted in a temperature of 200° C. at the wafer surface. The RF power for the argon plasma was set to 300 W and the growth ran for 7 cycles, where every cycle had a duration of 20 seconds. The gas flows in the CVD reactor can be seen in table A.1 below, showing the flow rate for the various gases used in PE-CVD:

A.1
Gas Flows for PE-CVD

| Precursor | Flow rate (SCCM) |
|---|---|
| Argon | 50 |
| Silane | 10 |
| Ammonia | 11.5 |

### Lithography

Before beginning the lithography it was ensured that no water or dust was on the wafer surfaces by blow drying the wafers with a nitrogen gun and then baking them at 200° C. on a hotplate for 10 minutes. After cooling to room temperature they were spin-coated with the bottom anti-reflection coating SF 3S, using an acceleration of 2500 RPM and a rotation speed of 2000 RPM for a duration of 45 seconds. Thereafter the wafers were again baked at 200° C. for 10 minutes and left to cool down to room temperature. The second resist layer was then applied by spin coating the wafers with the deep-UV resist PAR1085S90. Here the rotation speed was increased from 2000 to 4500 RPM, with the same acceleration as before. After spin coating the wafers were again baked on a hotplate, now at 90° C. for 1 minute.

Before exposure of the deep-UV resist the Talbot was loaded with a dummy mask and dummy wafer to ensure good alignment between mask and sample. The dummy mask was then switched to a mask with a pattern of hexagonal holes that were 200 nm in size and had a 500 nm pitch. The dummy wafer was also changed to Wafer 2, which was exposed first. For exposure the Talbot system was configured as in table A.2 below, showing information about the DTL set-up used.

A.2
Talbot Setup

| | |
|---|---|
| Light Source Wavelength (nm) | 193 |
| Dose (mJ/cm²) | 3.0, 3.25 or 3.5 |
| Frequency (Hz) | 100 |
| Separation (μm) | 80 |
| Talbot Distance (μm) | 8 |
| Polarization | None |
| Pulse Energy (mJ) | 1.5 |
| Power (μW/cm²) | 38 |

Wafer 2 was exposed with the doses 3.0 mJ/cm² on halve of the substrate and the other halve was exposed with 3.5 mJ/cm². Next Wafers 1 and 3 were exposed with a dose of 3.25 mJ/cm². After exposure of the resist the wafers were again baked on a hotplate to set the resist. This was done at 100° C. for 50 seconds. After cooling down to room temperature the resist was developed by submerging the wafers into developer MF24A for 60 seconds. After developing of the resists, the wafers were transferred to a beaker filled with DI-water. The wafers were left in the DI-water for 60 seconds and were then rinsed with softly flowing DI-water. The wafers were dried by running them on the spin coater with the same program used to apply the second layer of resist, with an acceleration of 2500 RPM and a rotation speed of 4500 RPM.

### Pattern Transfer

To etch the SiN mask of a wafer, it was placed on a graphite carrier and loaded into the reaction chamber of the RIE system. Gas flows and the pressure were set as specified in table A.3 below, showing the process-pressure and the gas flows for the RIE.

A.3
Pressure and Gas Flows for RIE

| | |
|---|---|
| Pressure (mTor) | 50 |
| CF4 (sccm) | 5 |
| CHF3 (sccm) | 5 |

After RIE, the wafer was dipped in a diluted HF solution, HF:H₂O at a ratio of 1:100. The wafer was dipped for a duration of 10 seconds and was then immediately transferred to a large beaker with DI water. This beaker was then placed under a stream of DI-water so that the beaker was overflowing. The wafer was left in the overflowing beaker for two minutes.

### Seed Particle Deposition

The deposition rate of the evaporator was set to 2 Å/s which resulted in an actual deposition rate of 1.8 Å/s. The wafers were deposited with 65.3 nm of gold, measured by a quartz crystal microbalance.

For lift-off of excessive gold, the wafers were placed in a beaker with Remover 1165 that was heated on a hotplate set to 100° C. The remover will remove both resist layers, thereby also the excess gold. To facilitate the lift-off, the beaker was alternatively moved from the hotplate to an ultrasonic bath with a bath temperature of 75° C. The wafers were also lifted from the beaker and rinsed under flowing Remover 1165 to further try to speed up the process. After some time the remover in the beaker was replaced so that no loose gold was scratching the surface of the wafer during sonication. When all excess gold was removed from the wafers they were transferred to a large beaker with DI-water which then are placed under running DI-water for 2 minutes.

### Wafer Dicing

To dice Wafer 1 into pieces that would exactly fit the holder for the electroplating a Disco DAD 3320 dicer was used. Before the actual dicing the wafer was spin coated with a thick layer of resist, LOR 30B, to protect the nanopattern from being contaminated or damaged during dicing. The wafer was then glued onto a holder using UV curable dicing tape and placed inside the dicer. The dicer was programmed to yield twelve 1×1 cm² pieces from the 2″ wafer. After dicing the wafer was dried using a nitrogen gun and the dicing tape was exposed to UV light for 2 minutes. After exposure the diced pieces were removed from the dicing tape. To remove the thick layer of resist on the substrates and any residues of the dicing tape on the backside, all diced pieces were placed in remover 1165 for 1 hour at 80° C. The pieces were then submerged and rinsed in DI-water followed by spin coating and baking on a hotplate for drying.

### Etch and Cover Run

The etch and cover run started with a flow of HCl at 750° C. for 60 minutes to assure that the liner and graphite susceptor were fully cleaned. After etching out the reactor, an InP or alternatively a GaP dummy growth was performed, thereby covering the liner walls and the susceptor surface with the desired material (i.e., InP or GaP). The InP dummy growth was done at 600° C. for 20 minutes and the GaP dummy growth at 630° C. for 30 minutes. Table A.4 below, shows the reactor temperatures and molar fractions (in arbitrary units) of the precursors used during different steps of the etch and cover runs.

A.4
Etch and Cover Run

| Stage | T (° C.) | T(min) | TMGa | TMIn | PH 3 | HCl |
|---|---|---|---|---|---|---|
| Etching | 750 | 60 | 0 | 0 | 0 | 2.69 × 10⁻³ |
| GaP Cover | 630 | 30 | 4.29 × 10⁻⁵ | 0 | 3.85 × 10⁻³ | 0 |
| Run | | | | | | |
| InP Cover | 600 | 20 | 0 | 6.54 × 10⁻⁵ | 6.92 × 10⁻³ | 0 |
| Run | | | | | | |

The growth recipes were started by heating the reactor, either up to 350° C. in the case of the In flush, or to 650° C. for the high temperature annealing. In either case, once the reactor temperature exceeded 300° C. the phosphine line was opened and was kept open until the reactor temperature dropped below 300° C. again, basically being open for the entire process.

For the In flush, which is an extra step used for growth in an GaP covered liner, the reactor temperature was stabilized at 350° C. for 2 minutes before TMIn was introduced by opening its line. The duration of the In flush determines the concentration of In in the gold seed particles and was adjusted for different samples, depending on the amount of gold that was in the reactor. It was observed that the optimum duration varied between 15 seconds and 1:40 minutes on the samples tested, which were as large as, or smaller than, 1×1 cm². The flush is terminated by closing the TMIn line and increasing the temperature of the reactor to 650° C. After this extra step, the structure of the recipes were the same for the InP or GaP covered liners.

For the high temperature annealing the reactor temperature was set to 650° C. Once the reactor temperature reached 650° C. the high temperature was held for 10 minutes for annealing under phosphine flow. After this annealing step the temperature was lowered to the growth temperature, which depends on the material to be grown. In some embodiments, the growth temperature may be from about 440° C. to about 480° C.

Once the reactor reached the growth temperature, a 2 minute temperature stabilization step was done before the growth was initiated. To begin growth the lines of the desired precursors were opened and to stop growth the lines were closed again. The duration of the growth step determined the length of the NWs. Longer growth times result in longer NWs. We typically used 5-8 minutes, depending on the sample. To finalize the growth the heating of the reactor was switched off and the phosphine line was closed once the reactor temperature dropped below 300° C.

### GaP Growth Recipe

To grow GaP the following precursors were introduced into the reactor: TMGa, phosphine and HCl. For details on the molar fractions of the different precursors see table A.S. The molar fraction of TMGa is different depending on if the sample is grown in an InP or GaP covered reactor. In the case of a GaP covered liner the molar fraction was increased by 40%, from 7.03×10⁻⁵ to 9.83×10⁻⁵ compared to when growing in an InP covered liner. In an embodiment, the In flush is only used when growing in a GaP covered liner, otherwise this step is skipped, since the indium in that case comes from the ambient in the reactor. Table A.5 below, shows the reactor temperatures and molar fractions (in arbitrary units) of the precursors used for the GaP growth.

A.5
GaP Growth Recipe

| Stage | T (° C.) | TMGa | TMAl | TMIn | PH 3 | HCl |
|---|---|---|---|---|---|---|
| Annealing | 650 | 0 | 0 | 0 | 2.31*10⁻² | 0 |
| GaP | 480 | 9.83*10⁻⁵ | 0 | 0 | 2.31*10⁻² | 1.85*10⁻⁴ |
| Growth | | | | | | |

### AlP Growth Recipe

The recipe is basically the same as for the GaP NWs except that the Group-III precursor, TMGa, is substituted with TMA1 and that no HCl is used. The molar fraction of TMA1 is approximately half as compared to TMGa, since TMA1 is a dimer rather than a monomer, see table A.6 below, showing the reactor temperatures and molar fractions (in arbitrary units) of the precursors used for the AlP growth.

A.6
AlP Growth Recipe

| Stage | T (° C.) | TMGa | TMAl | TMIn | PH 3 | HCl |
|---|---|---|---|---|---|---|
| In Flush | 350 | 0 | 0 | 8.91*10⁻⁵ | 6.92*10⁻³ | 0 |
| Annealing | 650 | 0 | 0 | 0 | 2.31*10⁻² | 0 |
| AlP | 440 | 0 | 3.48*10⁻⁵ | 0 | 2.31*10⁻² | 0 |
| Growth | | | | | | |

### AlP/GaP Hetero Growth Recipe

To grow GaP on AlP, the recipes of AlP and GaP were combined. Firstly, the substrate is introduced to a moderate amount of indium at low temperature (350° C.) to have the seed particles form an Au—In alloy. This Au—In alloy will act as the catalytic seed particle for the NW growth. Before growth, it is heated to high temperature (650 C) and annealed under phosphine flow for several minutes. After annealing, the substrate is cooled down to the growth temperature (440° C.), where the growth of AlP is initiated. Shortly before the material transition from AlP to GaP, HCl is introduced to facilitate the transition and the GaP growth. A 15 second delay was used between introducing HCl and switching precursors, meaning that HCl was turned on for the last 15 seconds of the AlP growth. To switch from the growth of AlP to GaP the Group-III precursors, TMA1 and TMGa, are simply switched once the growth of the AlP segment is finished. The first part of the GaP section is grown with a linearly increasing amount of Group III, and the remainder of the NW is grown with the molar fractions listed in Table A.7 below.

The reactor temperatures and molar fractions (in arbitrary units) of the precursors used for AlP/GaP growth are summarized in table A.7 below.

A.7
AlP/GaP Growth Recipe

| Stage | T (° C.) | TMGa | TMAl | TMIn | PH 3 | HCl |
|---|---|---|---|---|---|---|
| In Flush | 350 | 0 | 0 | 8.91*10⁻⁵ | 6.92*10⁻³ | 0 |
| Annealing | 650 | 0 | 0 | 0 | 2.31*10⁻² | 0 |
| AlP Growth | 440 | 0 | 3.48*10⁻⁵ | 0 | 2.31*10⁻² | 0 |
| GaP Growth | 440 | 7.03*10⁻⁵ | 0 | 0 | 2.31*10⁻² | 1.85*10⁻⁴ |

### Growth Characterization

To characterize the growth of the NW sample, the SEM images of the samples were analyzed using the software Image J. To get a value for the ratio of NWs that had grown straight compared to wires that had kinked the automated contrast based algorithms of the software were used. Five top-view images were taken with SEM at randomly chosen areas of the sample, however either at the center or edge, at a magnification of 30k. The software was used to calculate the number of straight wires per image. This data was then used to calculate straight NWs per area of this sample which then was compared to the value of a theoretical ideal sample.

### GaP Etch

The etch solution (diluted aqua regia, H₂O:HCl:HNO₃ at a ratio of 3:3:2) was tested at the temperatures 23° C. and 45° C. For high temperature only one duration was tested, 30 seconds. At room temperature different etch durations of 10, 30, 45, 60, 75, 90, 105, 120, 135, 165 and 195 seconds were tested.

To determine the etch rate the diameter of the NWs was measured before and after etching for every sample. This was done by imaging the NWs with SEM at 50k magnification and 30° tilt. The images were then analyzed in the software ImageJ, by measuring the diameter on 50 wires per sample. The diameter was measured on the top half as well as the lower half of each wire.

### AlP Etch

Different etching solutions were tested in an attempt to return the substrate to its configuration before seed particle definition, by removing any residues in the holes of the SiN mask leaving a clean and flat GaP surface. The etching solutions tested were DI-water (H₂O), diluted HCl mixtures (HCl:H₂O at 1:100, 1:10 and 1:1) and also a diluted piranha etch (H₂SO₄:H₂O₂:H₂O at 1:1:5). The etch durations tested for the different solutions were 1 and 5 minutes. The mixture of HCl:H₂O at 1:1 ratio is preferred.

The first samples were etched by simply submerging them in the etching solutions to investigate the effect of the etch on the wires, and to get an idea of their etch rate in different solutions. Nanowires were mechanically removed from their substrates by sonication. Etching was then performed to remove residues, such as stubs of AlP, remaining on the substrate to enable substrate reuse. All samples were characterized by SEM before and after etching.

### Etching for Substrate Reuse

The GaP segment of the NWs was harvested with a process which included a 10 minute sonication step to remove the wires. The substrates were thereafter etched in HCl:H₂O 1:1 for 1 minute. After etching they were transferred to a large beaker with DI-water which then was placed under flowing water for 2 minutes. After drying with a nitrogen gun they were exposed to another 10 minute sonication step in isopropanol. The samples were then etched further, but for different durations for different samples. Samples were etched for 2, 5, 10, 15 and 20 minutes in total. An etch duration of 5 minutes to 1 hour may be used.

For the second round of regrowth the substrates were etched for a much longer time of 1 hour or more.

### Electroplating

The electrolyte used for the gold deposition by electroplating is Gold Plating Services 24 K pure gold solution. For the experiments 160 ml of this solution was heated to 35° C. before deposition. The substrate was placed in a holder at an Au cathode. The cathode was placed at one end of the bath and a platinized titanium anode was placed at the other side of the bath. Between them a paddle agitator was installed which moved back and forth during deposition. The deposition was controlled by a signal generator, programmed as in Table A.8 below, showing the settings of the signal generator.

A.8
Signal for Electroplating

| | |
|---|---|
| J peak (mA/cm²) | 5 or 6.8 |
| Frequency (Hz) | 20 |
| Waveform | Square/Pulsed |
| Duty Cycle (%) | 20 |
| Duration (cycles) | 3500 or 4200 |

After electroplating the samples were thoroughly rinsed under softly flowing DI-water and then dried using a nitrogen gun. Lastly, before growth, the substrates were placed in an UV-Ozone cleaning system, FHR UVOH 150. The process lasted for 90 minutes, with the temperature set to 90° C. and the oxygen flow set to 500 sccm. For the second cycle of regrowth the number of deposition cycles during electroplating was set to 4200 on all the samples.

### Results

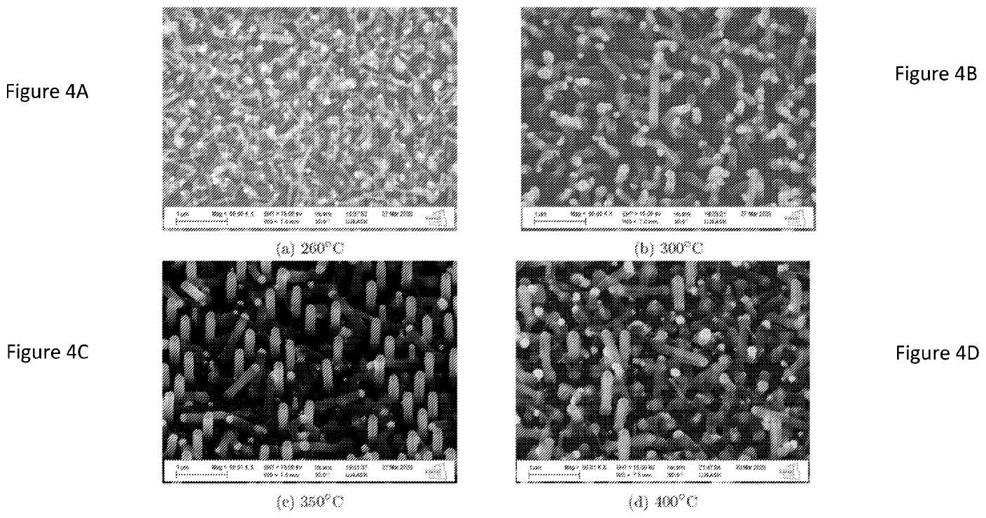

Theoretically there should be a sweet spot at 350° C. where TMIn will pyrolyze effectively but PH₃ (which is flowing during the In flush) will not, or at least not to the extent where growth would occur. At lower temperatures TMIn does not pyrolyze enough and at higher temperatures there is a risk of growing some InP stub under the gold particle. In consensus with this theory, the best result was obtained at 350° C., which can be seen in the micrographs of FIGS. 4A-4D. In general, a temperature range of 260 to 400° C. may be used for the In flush.

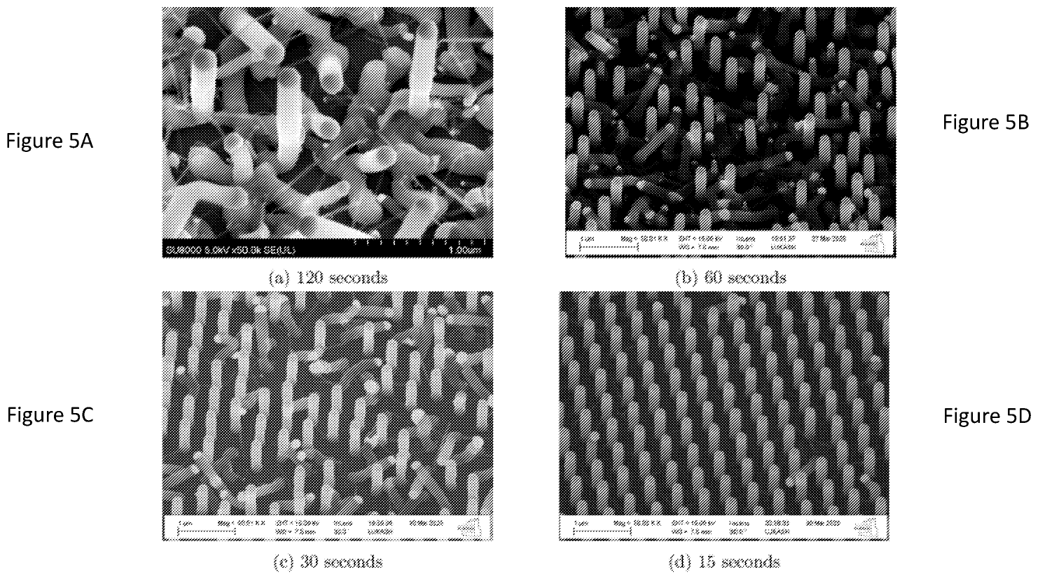

To further fine tune the indium concentration in the seed particles, different durations of the flush were investigated. It showed to be favorable to only flush for a short time for small substrates, as can be seen in the micrographs of FIGS. 5A-5D. For example, for the small substrates, 15 second flush time was optimum. The sharp time dependence indicates that the growth of AlP is very sensitive to the amount of In in the gold particle. What exactly the role of the In is regarding the growth is still unclear. Without wishing to be bound by a particular theory, it is assumed that the indium alloying changes the wetting angle, the saturation level of aluminum or the melting point of the alloyed gold particle or perhaps it could catalyze chemical reactions. It could also be a combination of the alternatives listed above, or have some other unknown effect.

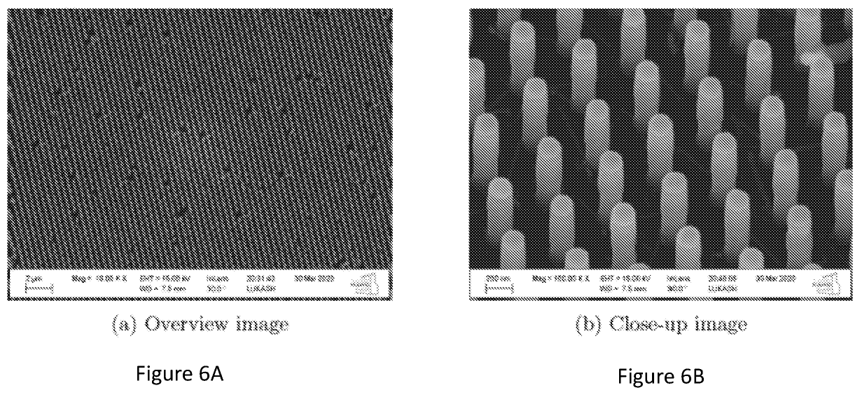

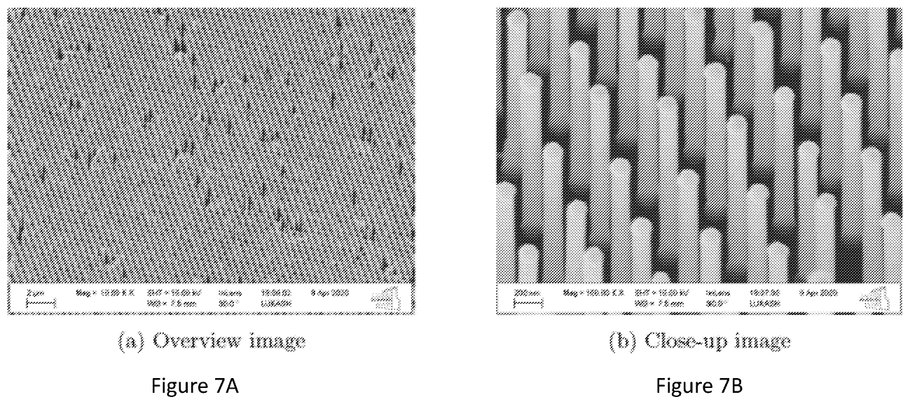

With optimization of the In flush and the growth conditions, AlP segments could be grown with yields as high as 96%. The final results of the AlP growth can be seen in the micrographs of FIGS. 6A and 6B. Since there are relatively many sections where the growth is perfect, this indicates that the kinked nanowires do not kink due to effects from the growth conditions but rather that they might be affected by the imperfect seed particle definition and/or the SiN mask.

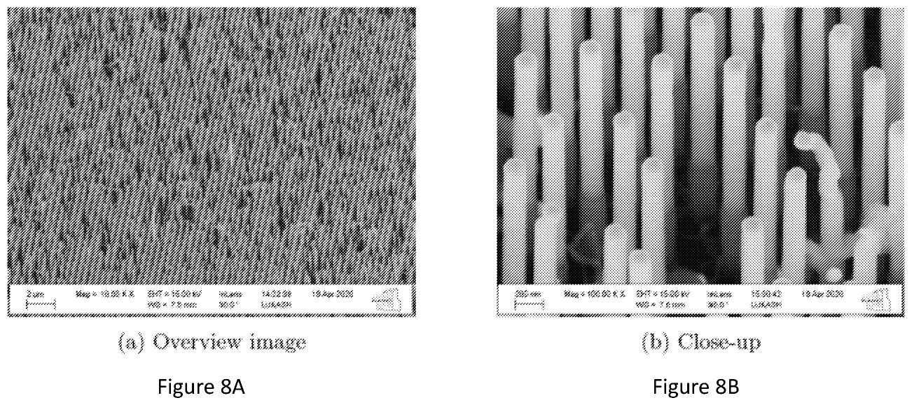

For the regrowth experiments the growth parameters needed to be adjusted for larger 1×1 cm² samples. The limiting factor appeared to be the In flush. Nothing grew on the new samples until the duration of the In flush was increased drastically. When increased slightly only wires at the edges of the substrates grew, suggesting that the amount of In in the particles at the center still was too low. The new optimum duration of the In flush was found to be 1:40 minutes for the 1×1 cm² substrates, as shown in the micrographs of FIGS. 8A and 8B. The reason that the In flush had to be increased drastically, from 15 seconds to 1:40 minutes, is that the amount of gold in the reactor is now much higher than before when smaller substrates are used. Thus, the In flush duration may range from 10 to 120 seconds, such as from 15 to 100 seconds, depending on the substrate size and/or the amount of gold present on the substrate. For example, longer In flush durations may be used with larger wafer sizes.

The AlP growth showed to be very sensitive to the amount of In in the gold particle. Since only a small amount of TMIn is introduced into the reactor, assuming that nearly all precursor reacts and is distributed fairly equally on the substrate it is logical that the amount of In is now lower in each gold seed particle on the new substrate pieces compared to the small substrates used for growth optimization.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of growing nanowires (NWs), comprising:
forming catalyst particles comprising a gold-indium alloy on portions of a semiconductor substrate that are exposed by openings of a template layer disposed on the substrate; and
growing the NWs comprising a compound semiconductor material under the catalyst particles.

2. The method of claim 1, wherein the step of forming catalyst particles comprises:
depositing gold particles on the exposed portions of the substrate; and
performing an indium flush to alloy the gold particles with indium to form the catalyst particles which comprise a gold-indium alloy.

3. The method of claim 2, wherein the step of performing the indium flush comprises providing an indium metalorganic vapor into a reaction chamber containing the substrate, at a temperature between 260° C. and 400° C., for at least 10 seconds.

4. The method of claim 1, wherein:
the step of growing the NWs comprises growing aluminum phosphide (AlP) nanowire stubs between the substrate and the catalyst particles; and
the substrate comprises gallium phosphide (GaP).

5. The method of claim 4, wherein the step of growing the NWs further comprises growing GaP NWs between the AlP nanowire stubs and the catalyst particles.

6. The method of claim 5, further comprising:
removing the GaP NWs from the substrate by separating the GaP NWs from the AlP nanowire stubs; and
removing the AlP nanowire stubs from the substrate after separating the GaP NWs from the AlP nanowire stubs.

7. The method of claim 6, wherein:
the step of removing the GaP NWs from the substrate comprises using sonication or a polymer matrix to separate the GaP NWs from the AlP nanowire stubs; and
the step of removing the AlP nanowire stubs from the substrate comprises selectively etching the AlP nanowire stubs.

8. The method of claim 6, further comprising reusing the substrate to grow additional GaP NWs after removing the AlP nanowire stubs.

9. The method of claim 8, wherein the step of reusing the substrate comprises repeating at least 3 times the steps of forming the catalyst particles, growing the AlP nanowire stubs, and growing the GaP NWs between the AlP nanowire stubs and the catalyst particles.

10. A method of growing nanowires (NWs), comprising:
depositing gold particles on portions of a gallium phosphide (GaP) substrate;
performing an indium flush to alloy the gold particles with indium to form gold-indium alloy catalyst particles;
growing aluminum phosphide (AlP) nanowire stubs between the substrate and the catalyst particles; and
growing GaP NWs between the AlP nanowire stubs and the catalyst particles.

11. The method of claim 10, wherein the step of performing the indium flush comprises heating the substrate to a temperature ranging from 260° C. to 400° C., while providing an indium-containing vapor to the substrate.

12. The method of claim 11, wherein the indium-containing vapor is provided for a time period ranging from 10 seconds to 120 seconds.

13. The method of claim 10, further comprising annealing the substrate after the step of performing the indium flush and before the step of growing the AlP nanowire stubs, the annealing comprising:
heating the substrate at a temperature ranging from 625° C. to 675° C., while flowing a phosphine-containing vapor to the substrate; and
then cooling the substrate to a temperature ranging from 415° C. to about 465° C.

14. The method of claim 13, wherein the step of growing the AlP nanowire stubs comprises maintaining the substrate at the temperature ranging from 415° C. to about 465° C., while flowing a phosphine-containing and aluminum-containing vapor to the substrate.

15. The method of claim 14, wherein the phosphine-containing and aluminum-containing vapor comprises phosphine (PH₃) and trimethylaluminum (TMAl).

16. The method of claim 14, wherein the step of growing the GaP NWs comprises:
stopping the flow of the aluminum-containing vapor to the substrate;
flowing an acid to the substrate; and
flowing a phosphine-containing and gallium-containing vapor to the substrate.

17. The method of claim 16, wherein after the step of flowing the phosphine-containing and aluminum-containing vapor is stopped, the step of flowing the acid occurs for a time period of at least 10 seconds, before the step of flowing the gallium-containing vapor begins.

18. The method of claim 17, wherein:
the step of growing the GaP NWs comprises initially growing the GaP NWs with a linearly increasing amount of gallium from a first amount to a higher second amount, followed by growing the GaP NWs with the second amount of gallium for a predetermined time;
the acid comprises HCl; and
the phosphine-containing and gallium-containing vapor comprises phosphine (PH₃) and trimethylgallium (TMGa).

19. The method of claim 17, further comprising:
removing the GaP NWs from the substrate by separating the GaP NWs from the AlP nanowire stubs; and
selectively etching the AlP nanowire stubs to remove the AlP nanowire stubs from the substrate.

20. The method of claim 19, further comprising reusing the substrate to repeat at least 3 times the steps of depositing the gold particles, performing the indium flush, growing the AlP nanowire stubs, and growing the GaP NWs.
